(19) United States
(12) Patent Application Publication
(10) Pub. No.: US 2025/0167803 A1
(43) Pub. Date: May 22, 2025

(54) DATA TRANSMISSION METHOD AND APPARATUS

(71) Applicant: HUAWEI TECHNOLOGIES CO., LTD., Shenzhen (CN)

(72) Inventors: Jiahui LI, Shenzhen (CN); Mengyao MA, Shenzhen (CN); Yinggang DU, Shenzhen (CN); Xun YANG, Singapore (SG)

(21) Appl. No.: 19/027,479

(22) Filed: Jan. 17, 2025

Related U.S. Application Data
(63) Continuation of application No. PCT/CN2022/106473, filed on Jul. 19, 2022.

(51) Int. Cl. H03M 7/30; H04L 69/04; H04W 28/06

(52) U.S. Cl. CPC H03M 7/3066; H04L 69/04; H04W 28/06

(57) ABSTRACT

This application provides a data transmission method and an apparatus. The method includes: A transmit end obtains to-be-sent data; the transmit end obtains a plurality of data blocks based on the to-be-sent data; and the transmit end compresses a first data block based on a compression mode and sends a compressed first data block, where the first data block is one of the plurality of data blocks. Therefore, a plurality of data blocks may be separately compressed by using a same compression mode or different compression modes, and compressed data blocks are sent.

### CROSS-REFERENCE TO RELATED APPLICATIONS

This application is a continuation of International Application No. PCT/CN2022/106473, filed on Jul. 19, 2022, the disclosure of which is hereby incorporated by reference in its entirety.

### TECHNICAL FIELD

This application relates to the field of mobile communication technologies, and in particular, to a data transmission method and an apparatus.

### BACKGROUND

Sensing and imaging are potential technologies and new application scenarios for future communication systems such as a cellular communication system and a wireless fidelity (wireless fidelity, Wi-Fi) communication system. In the future, devices such as mobile terminals, sensors, and base stations can perform environment sensing and imaging by using electromagnetic signals, to perform offline or real-time modeling and analysis on a wireless transmission environment. Eventually, performance of the communication system is significantly improved. Because a computing capability and a battery capacity of a single device and an environment range that can be sensed by the single device are limited, a sensing and imaging result needs to be sent to a remote central node (which may be a base station, a server, a cloud computing center, a terminal device with strong computing power, or the like) in a backhaul manner for information convergence. Because collection of a plurality of broadband frequencies and electromagnetic signals in different directions is involved, and a large amount of data for sensing and imaging data is obtained, a compression operation needs to be performed before wireless backhaul is performed, to reduce consumption of wireless transmission resources.

Due to complexity of physical-layer data such as sensing data and imaging data, when the physical-layer data such as the sensing data and the imaging data is compressed and transmitted in a current data compression and transmission manner, problems of low compression efficiency and poor transmission robustness exist, resulting in a reduction in transmission performance.

### SUMMARY

This application provides a data transmission method and an apparatus, to improve compression efficiency and transmission robustness of physical-layer data, and improve communication performance.

According to a first aspect, this application provides a data transmission method, to improve compression efficiency and transmission robustness of physical-layer data, and improve communication performance. The method may be implemented by a transmit end, and the transmit end may be a device or an apparatus that compresses data and sends compressed data. For example, the transmit end may be a terminal device, a network device, a component in the terminal device, or a component in the network device. The component in this application may include, for example, at least one of a processor, a transceiver, a processing unit, or a transceiver unit. For example, an execution entity is the transmit end. The method may be implemented through the following steps: The transmit end obtains to-be-sent data; the transmit end obtains a plurality of data blocks based on the to-be-sent data; and the transmit end compresses a first data block based on a compression mode and sends a compressed first data block, where the first data block is one of the plurality of data blocks.

Based on the method described in the first aspect, the transmit end may obtain the plurality of data blocks based on the to-be-transmitted data, and compress the first data block in the plurality of data blocks based on the compression mode. It may be understood that the to-be-transmitted data herein includes but is not limited to the physical-layer data. Therefore, the plurality of data blocks obtained based on the to-be-transmitted data may be separately compressed by using a same compression mode or different compression modes, and compressed data blocks are sent, so that data compression efficiency can be improved, and transmission robustness can be improved, to improve communication performance.

In a possible design, the transmit end may further send compression mode information, where the compression mode information indicates the compression mode. Therefore, a receive end may receive the compression mode information, and restore the first data block based on the compression mode indicated by the compression mode information, to improve efficiency and a success rate of data restoration, and improve data transmission efficiency.

In a possible design, the compression mode information includes one bit in a bitmap, and the bitmap indicates compression modes of the plurality of data blocks. Based on this design, the compression mode information may be sent in a form of the bitmap, to improve indication flexibility and indication efficiency of the compression mode.

In a possible design, the compression mode information indicates that the compression mode is one of independent compression and reference compression. The independent compression means that compression of another data block is not referenced in a compression process of the first data block, and the reference compression means that the first data block is compressed based on a previous data block. Based on this design, data block compression can be flexibly implemented, data compression efficiency is further improved, and transmission robustness is further improved.

In a possible design, the previous data block is a data block whose transmission time point is closest to a transmission time point of the first data block, and the previous data block is a successfully received data block; or the previous data block is a data block that enables a compression rate of the first data block to be highest, and the previous data block is a successfully received data block. Based on this design, flexibility of data block compression can be further improved, data compression efficiency is further improved, and transmission robustness is further improved.

In a possible design, the transmit end may further send the transmission time point of the previous data block. Therefore, the receive end may learn of, based on the transmission time point of the previous data block, the previous data block that is referenced for compression of the first data block, so that the receive end restores the first data block, to further improve efficiency and a success rate of data restoration.

In a possible design, the transmit end may further receive feedback information, where the feedback information indicates whether the first data block is received successfully. It may be understood that, in this application, the transmit end may further receive feedback information for the previous data block. Therefore, the transmit end may determine, based on the feedback information, whether a data block is received successfully, to improve transmission reliability.

In a possible design, an interval between a transmission time point of the feedback information and the transmission time point of the first data block is not less than k time units, and k is a positive integer. Based on this design, the transmission time point of the feedback information can be prevented from being excessively close to a transmission time point of the data block, and time is reserved for processing and restoring the data block by the receive end, to improve data transmission reliability.

In a possible design, the feedback information includes information indicating that the first data block is received successfully; or the feedback information includes information indicating that a transmission unit is received successfully, and the transmission unit is occupied by the first data block. Based on this design, flexibility of reference information can be improved.

In a possible design, a distance between the transmission time point of the previous data block and the transmission time point of the first data block does not exceed first duration. The first duration is a specified value. Alternatively, the transmit end may receive indication information of the first duration; or the transmit end may send indication information of the first duration. Based on this design, an excessively long time interval between the first data block and a data block referenced by the first data block can be avoided, and compression efficiency and transmission robustness can be further improved.

In a possible design, the transmit end may further send first information, where the first information is used for determining a transmission unit occupied by the first data block or a quantity of transmission units occupied by the first data block. Based on this design, the receive end may determine, based on the first information, the transmission unit occupied by the first data block or the quantity of transmission units occupied by the first data block, to improve data restoration efficiency and data transmission robustness, and improve transmission performance.

In a possible design, the first information includes at least one of the following information: a number of a data block corresponding to a transmission unit in which the first information is located; a quantity of data blocks corresponding to the transmission unit in which the first information is located; location information of a transmission unit corresponding to a data block; information indicating whether a data block is carried in different transmission units; and information indicating that a data block ends. Based on this design, the transmission unit occupied by the first data block can be flexibly indicated.

In a possible design, the transmit end may receive or send second information, where the second information indicates a mapping relationship between the to-be-sent data and the plurality of data blocks. Based on this design, the transmit end and the receive end may agree on a manner of obtaining the plurality of data blocks based on the to-be-transmitted data, so that the receive end may restore the plurality of data blocks into complete data based on the mapping relationship, to improve data restoration efficiency and reliability, and improve transmission performance.

In a possible design, the second information specifically indicates that the to-be-sent data is evenly divided into the plurality of data blocks; or the second information includes a mapping relationship between a plurality of data segments of the to-be-sent data and a data block, where the mapping relationship is determined based on a proportion of data that is in the data segments and whose value is a specific value and a proportion of data that corresponds to the data block and whose value is the specific value; or the to-be-sent data includes three-dimensional data, and the second information includes a mapping relationship between a data block and a coordinate range of the three-dimensional data; or the to-be-sent data includes data of an AI model, and the second information includes a mapping relationship between a data block and a network layer of the AI model. Based on this design, the mapping relationship between the to-be-transmitted data and the data block can be flexibly determined, so that compression efficiency and transmission robustness of different data are improved, to further improve transmission performance.

In a possible design, the feedback information indicates that the first data block is not received successfully, and the transmit end may further send third information, where the third information indicates to stop retransmitting the first data block. Based on this design, when the data block is not received successfully, if an excessive quantity of time-frequency resources are occupied for the retransmission of the data block, the third information may indicate that the retransmission of the data block is stopped, to improve transmission efficiency of an initially transmitted data block. For example, the third information may include an NDI and/or a retransmission indication.

According to a second aspect, this application provides a data transmission method, to improve compression efficiency and transmission robustness of physical-layer data, and improve communication performance. The method may be implemented by a receive end, and the receive end may be a device or an apparatus that receives compressed data and decompresses the compressed data to restore the data. For example, the receive end may be a terminal device, a network device, a component in the terminal device, or a component in the network device. The component in this application may include, for example, at least one of a processor, a transceiver, a processing unit, or a transceiver unit. For example, the execution entity is the receive end. The method may be implemented through the following steps: The receive end receives a compressed first data block, and decompresses the first data block based on a compression mode of the first data block. The receive end may further restore a plurality of data blocks into to-be-sent data, where the plurality of data blocks include the first data block.

Based on the method described in the second aspect, the receive end may decompress the plurality of data blocks based on respective compression modes of the plurality of data blocks, and restore to-be-transmitted data based on the plurality of data blocks. It may be understood that the to-be-transmitted data herein includes but is not limited to the physical-layer data. Therefore, the plurality of data blocks obtained based on the to-be-transmitted data may be separately compressed by using a same compression mode or different compression modes, and compressed data blocks are sent, so that data compression efficiency can be improved, and transmission robustness can be improved, to improve communication performance.

In a possible design, the receive end may further receive compression mode information, where the compression mode information indicates the compression mode.

In a possible design, the compression mode information includes one bit in a bitmap, and the bitmap indicates compression modes of the plurality of data blocks.

In a possible design, the compression mode information indicates that the compression mode is one of independent compression and reference compression. The reference compression is to compress the first data block based on a previous data block.

In a possible design, the previous data block is a data block whose transmission time point is closest to a transmission time point of the first data block, and the previous data block is a successfully received data block; or the previous data block is a data block that enables a compression rate of the first data block to be highest, and the previous data block is a successfully received data block.

In a possible design, the receive end may further receive the transmission time point of the previous data block.

In a possible design, the receive end may further send feedback information, where the feedback information indicates whether the first data block is received successfully.

In a possible design, an interval between a transmission time point of the feedback information and the transmission time point of the first data block is not less than k time units, and k is a positive integer.

In a possible design, the feedback information includes information indicating that the first data block is received successfully; or the feedback information includes information indicating that a transmission unit is received successfully, and the transmission unit is occupied by the first data block.

In a possible design, a distance between the transmission time point of the previous data block and the transmission time point of the first data block does not exceed first duration, where the first duration is a specified value, or the receive end may further send or receive indication information of the first duration.

In a possible design, the receive end may further receive first information, where the first information is used for determining a transmission unit occupied by the first data block or a quantity of transmission units occupied by the first data block.

In a possible design, the first information includes at least one of the following information: a number of a data block corresponding to a transmission unit in which the first information is located; a quantity of data blocks corresponding to the transmission unit in which the first information is located; location information of a transmission unit corresponding to a data block; information indicating whether a data block is carried in different transmission units; and information indicating that a data block ends.

In a possible design, the receive end may further receive or send second information, where the second information indicates a mapping relationship between the to-be-sent data and the plurality of data blocks.

In a possible design, the second information specifically indicates that the to-be-sent data is evenly divided into the plurality of data blocks; or the second information includes a mapping relationship between a plurality of data segments of the to-be-sent data and a data block, where the mapping relationship is determined based on a proportion of data that is in the data segments and whose value is a specific value and a proportion of data that corresponds to the data block and whose value is the specific value; or the to-be-sent data includes three-dimensional data, and the second information includes a mapping relationship between a data block and a coordinate range of the three-dimensional data; or the to-be-sent data includes data of an AI model, and the second information includes a mapping relationship between a data block and a network layer of the AI model.

In a possible design, the feedback information indicates that the first data block is not received successfully, and the receive end may further receive third information, where the third information indicates to stop retransmitting the first data block.

For beneficial effects of the possible designs of the second aspect, refer to descriptions of beneficial effects of the possible designs of the first aspect.

According to a third aspect, a data transmission apparatus is provided. The apparatus may implement the method according to any possible design of the first aspect. The apparatus has functions of the foregoing receive end. The apparatus is, for example, a receive end, or a functional module or the like in the receive end.

Alternatively, the apparatus may implement the method according to the second aspect and any possible design of the second aspect. The apparatus has functions of the foregoing transmit end. The apparatus is, for example, a transmit end, or a functional module or the like in the transmit end.

In an optional implementation, the apparatus may include modules that perform and that are in one-to-one correspondence with the method/operations/steps/actions described in the first aspect or the second aspect. The module may be a hardware circuit, or may be software, or may be implemented by a hardware circuit in combination with software. In an optional implementation, the apparatus includes a processing unit (sometimes also referred to as a processing module) and a transceiver unit (sometimes also referred to as a transceiver module). The transceiver unit can implement a sending function and a receiving function. When the transceiver unit implements the sending function, the transceiver unit may be referred to as a sending unit (sometimes also referred to as a sending module). When the transceiver unit implements the receiving function, the transceiver unit may be referred to as a receiving unit (sometimes also referred to as a receiving module). The sending unit and the receiving unit may be a same functional module, the functional module is referred to as a transceiver unit, and the functional module can implement the sending function and the receiving function. Alternatively, the sending unit and the receiving unit may be different functional modules, and the transceiver unit is a collective term for these functional modules.

For example, when the apparatus is configured to perform the method described in the first aspect, the apparatus may include the processing unit and the transceiver unit. The processing unit may be configured to obtain to-be-sent data, and obtain a plurality of data blocks based on the to-be-sent data. The transceiver unit may be configured to compress a first data block based on a compression mode and send a compressed first data block.

Optionally, the transceiver unit may be configured to send at least one of compression mode information, a transmission time point of a previous data block, indication information of first duration, first information, second information, and third information. In addition, optionally, the transceiver unit may be further configured to receive at least one of feedback information, feedback information of the first duration, and the second information.

For the compression mode information, the transmission time point of the previous data block, the indication information of the first duration, the first information, the second information, and the third information, refer to the descriptions in the first aspect.

For example, when the apparatus is configured to perform the method described in the second aspect, the apparatus may include the processing unit and the transceiver unit. The transceiver unit may be configured to receive a compressed first data block. The transceiver unit may be configured to receive the compressed first data block. The processing unit may be configured to decompress the first data block based on a compression mode of the first data block, and restore a plurality of data blocks including the first data block into the to-be-sent data.

Optionally, the transceiver unit may be configured to receive at least one of compression mode information, a transmission time point of a previous data block, indication information of first duration, first information, second information, and third information. In addition, optionally, the transceiver unit may be further configured to send at least one of feedback information, feedback information of the first duration, and the second information.

For the compression mode information, the transmission time point of the previous data block, the indication information of the first duration, the first information, the second information, and the third information, refer to the descriptions in the first aspect.

For another example, the apparatus may include a processor, coupled to a memory and configured to execute instructions in the memory, to implement the method in the first aspect or the second aspect. Optionally, the apparatus may further include another component, for example, an antenna, an input/output module, and an interface. These components may be hardware, software, or a combination of software and hardware.

According to a fourth aspect, a computer-readable storage medium is provided. The computer-readable storage medium is configured to store a computer program or instructions. When the computer-readable storage medium is run, the method in one of the first aspect and the second aspect is implemented.

According to a fifth aspect, a computer program product including instructions is provided. When the computer program product runs on a computer, the method in one of the first aspect and the second aspect is implemented.

According to a sixth aspect, a chip system is provided. The chip system includes a logic circuit (which may alternatively be understood as that the chip system includes a processor, and the processor may include a logic circuit and the like), and may further include an input/output interface. The input/output interface may be configured to perform receiving, or may be configured to perform sending. For example, when the chip system is configured to implement a function of a transmit end, the input/output interface may be configured to obtain to-be-transmitted data, and/or send a compressed first data block. The input/output interface may be a same interface, that is, a same interface can implement both a sending function and a receiving function. Alternatively, the input/output interface includes an input interface and an output interface. The input interface is configured to implement a receiving function, that is, is configured to receive a message. The output interface is configured to implement a sending function, that is, is configured to send a message. The logic circuit may be configured to perform an operation other than the receiving and sending functions in the first aspect and the second aspect. The logic circuit may be further configured to transmit a message to the input/output interface, or receive, from an input/output interface, a message from another communication apparatus. The chip system may be configured to implement the method in one of the first aspect and the second aspect. The chip system may include a chip, or may include a chip and another discrete component.

Optionally, the chip system may further include a memory, and the memory may be configured to store instructions. The logic circuit may invoke the instructions stored in the memory to implement a corresponding function.

According to a seventh aspect, a communication system is provided. The communication system may include a receive end and a transmit end. The receive end may be configured to perform the method performed by the receive end in the first aspect, and the transmit end may be configured to perform the method performed by the transmit end in the second aspect. Alternatively, the communication system may include an apparatus configured to perform the method according to the first aspect, and include an apparatus configured to perform the method according to the second aspect.

For technical effect brought by the second aspect to the seventh aspect, refer to the descriptions of the first aspect. Details are not described herein again.

### BRIEF DESCRIPTION OF DRAWINGS

FIG. 1 is a diagram of an architecture of a wireless communication system according to this application;

FIG. 2a is a diagram of an architecture of a communication protocol stack;

FIG. 2b is a diagram of an architecture of another communication protocol stack;

FIG. 3 is a schematic flowchart of a communication method according to an embodiment of this application;

FIG. 4 is a diagram of a manner for obtaining a data block according to an embodiment of this application;

FIG. 5 is a diagram of another manner for obtaining a data block according to an embodiment of this application;

FIG. 6 is a diagram of another manner for obtaining a data block according to an embodiment of this application;

FIG. 7 is a diagram of a reference compression mode according to an embodiment of this application;

FIG. 8 shows a data block status list according to an embodiment of this application;

FIG. 9 shows another data block status list according to an embodiment of this application;

FIG. 10 is a diagram of a relationship between feedback information and a transmission time point of a data block according to an embodiment of this application;

FIG. 11 is a diagram of a structure of feedback information according to an embodiment of this application;

FIG. 12 is a diagram of a structure of other feedback information according to an embodiment of this application;

FIG. 13 is a diagram of a structure of a communication apparatus according to an embodiment of this application;

FIG. 14 is a diagram of a structure of another communication apparatus according to an embodiment of this application; and

FIG. 15 is a diagram of a structure of another communication apparatus according to an embodiment of this application.

### DESCRIPTION OF EMBODIMENTS

Technical solutions in embodiments of this application are described below with reference to the accompanying drawings in embodiments of this application. In the descriptions of this application, unless otherwise specified, “/” indicates that associated objects are in an “or” relationship. For example, A/B may indicate A or B. In this application, “and/or” describes only an association relationship between associated objects and indicates that three relationships may exist. For example, A and/or B may indicate: Only A exists, both A and B exist, and only B exists, where A and B may be singular or plural. In addition, in the descriptions of this application, “a plurality of” means two or more than two unless otherwise specified. At least one of the following items (pieces) or a similar expression thereof indicates any combination of these items, including a single item (piece) or any combination of a plurality of items (pieces). For example, at least one item (piece) of a, b, or c may indicate: a, b, c, a and b, a and c, b and c, or a, b, and c, where a, b, and c may be singular or plural. In addition, to clearly describe the technical solutions in embodiments of this application, terms such as “first” and “second” are used in embodiments of this application to distinguish between same items or similar items that provide basically same functions or purposes. A person skilled in the art may understand that the terms such as “first” and “second” do not limit a quantity or an execution sequence, and the terms such as “first” and “second” do not indicate a definite difference.

In addition, a network architecture and a service scenario described in embodiments of this application are intended to describe the technical solutions in embodiments of this application more clearly, but do not constitute a limitation on the technical solutions provided in embodiments of this application. A person of ordinary skill in the art may learn that the technical solutions provided in embodiments of this application are also applicable to similar technical problems as the network architecture evolves and a new service scenario emerges.

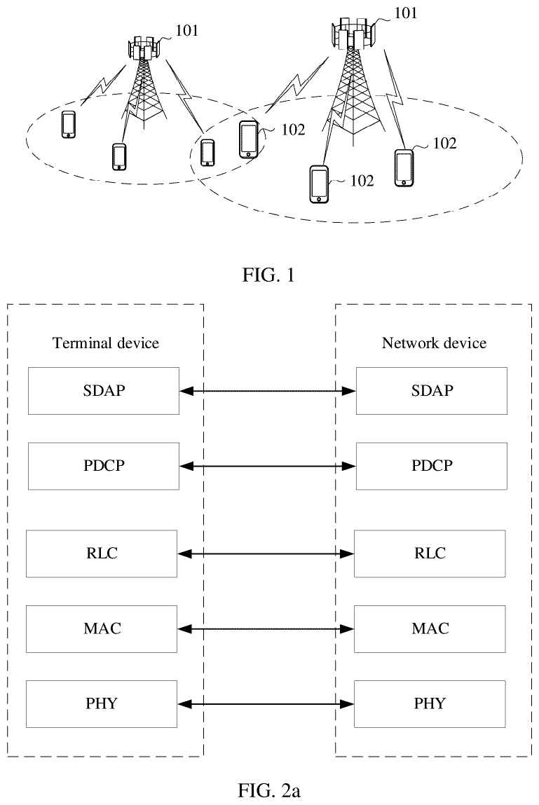

For ease of understanding embodiments of this application, a communication system shown in FIG. 1 is first used as an example to describe a communication system used in embodiments of this application. FIG. 1 shows a possible architecture of a communication system to which a method provided in an embodiment of this application is applicable. The architecture of the communication system includes a network device 101 and at least one terminal device 102. The network device may establish a communication link to the at least one terminal device (for example, the terminal device 1 and the terminal device 2 shown in the figure) by using beams in different directions. The network device may provide the at least one terminal device with a service related to wireless access, to implement one or more of the following functions: a wireless physical layer function, resource scheduling and radio resource management, quality of service (quality of service, QoS) management, radio access control, and a mobility management function. The at least one terminal device may also form a beam for data transmission with the network device. In this embodiment, the network device may communicate with the at least one terminal device by using the beam.

It should be understood that, the network device in embodiments of this application may be any device having a wireless transceiver function or a chip that may be disposed in the device. The device includes but is not limited to an evolved NodeB (evolved NodeB, eNB), a radio network controller (radio network controller, RNC), a NodeB (NodeB, NB), a base station controller (base station controller, BSC), a base transceiver station (base transceiver station, BTS), a home base station (for example, a home evolved NodeB (home evolved NodeB), or a home NodeB (home NodeB, HNB)), a baseband unit (baseband unit, BBU), or an access point (access point, AP), a wireless relay node, a wireless backhaul node, a transmission point (transmission point, TP), a transmission reception point (transmission reception point, TRP/TP), a remote radio head (remote radio head, RRH), or the like in a wireless fidelity (wireless fidelity, Wi-Fi) system, or may be a gNB (gNB) or a transmission point in a 5G, for example, an NR system, or one antenna panel or one group (including a plurality of antenna panels) of antenna panels of a base station in the 5G system, or may be a network node that forms a gNB or a transmission point, for example, a baseband unit or a distributed unit (distributed unit, DU), a satellite, an unmanned aerial vehicle, or the like. Alternatively, the network device may be a radio controller in a cloud radio access network (cloud radio access network, CRAN) scenario, or the network device may be a relay station, an access point, a vehicle-mounted device, a wearable device, an access network device (for example, a gNB) in a future 5G network, an access network device in a future evolved PLMN network, or the like. This is not limited in embodiments of this application.

In some deployments, the gNB may include a central unit (central unit, CU) and a DU. The gNB may further include an active antenna unit (active antenna unit, AAU). The CU implements some functions of the gNB, and the DU implements some functions of the gNB. For example, the CU is responsible for processing a non-real-time protocol and service, and implements functions of a radio resource control (radio resource control, RRC) layer and a packet data convergence protocol (packet data convergence protocol, PDCP) layer. The DU is responsible for processing a physical layer protocol and a real-time service, and implements functions of a radio link control (radio link control, RLC) layer, a media access control (media access control, MAC) layer, and a physical (physical, PHY) layer. The AAU implements some physical layer processing functions, radio frequency processing, and a function related to an active antenna. Information at the RRC layer is eventually converted into information at the PHY layer, or is converted from information at the PHY layer. Therefore, in this architecture, higher layer signaling such as RRC layer signaling may also be considered as being sent by the DU or sent by the DU and the AAU. It may be understood that the network device may be a device including one or more of a CU node, a DU node, and an AAU node. In addition, the CU may be classified into a network device in an access network (radio access network, RAN), or the CU may be classified into a network device in a core network (core network, CN). This is not limited in this application.

For example, the network device may be used as a scheduling device. In this case, the network device may include, for example, but is not limited to: an LTE eNodeB eNB, an NR gNodeB gNB, an operator, and the like. Functions thereof may include, for example, configuring uplink and downlink resources, and sending downlink control information (downlink control information, DCI) in a scheduling mode of the base station. For example, the network device may further serve as a sending device. In this case, the network device may include, for example, but is not limited to: TRP and RRH, and functions of the network device may include, for example: sending downlink signals and receiving uplink signals.

The terminal device in this application may also be referred to as a user equipment (user equipment, UE), an access terminal, a subscriber unit, a subscriber station, a mobile station, a mobile console, a remote station, a remote terminal, a mobile device, a user terminal, a terminal, a wireless communication device, a user agent, or a user apparatus. The terminal device may be a cellular phone, a cordless phone, a session initiation protocol (session initiation protocol, SIP) phone, a wireless local loop (wireless local loop, WLL) station, a personal digital assistant (personal digital assistant, PDA), a handheld device having a wireless communication function, a computing device, another processing device connected to a wireless modem, a vehicle-mounted device, a wearable device, a terminal device in a future 5G network, or a terminal device in a future evolved public land mobile network (public land mobile network, PLMN). This is not limited in embodiments of this application. The terminal device in embodiments of this application may be a mobile phone (mobile phone), a pad (pad), a computer having a wireless transceiver function, a wearable device, a virtual reality (virtual reality, VR) terminal device, an augmented reality (augmented reality, AR) terminal device, a wireless terminal in industrial control (industrial control), a wireless terminal in self-driving (self-driving), a wireless terminal in telemedicine (remote medical), a wireless terminal in a smart grid (smart grid), a wireless terminal in transportation safety (transportation safety), a wireless terminal in a smart city (smart city), a wireless terminal in a smart home (smart home), or the like. Application scenarios are not limited in embodiments of this application. In this application, the terminal device and a chip that may be disposed in the terminal device are collectively referred to as a terminal device.

The functions of the terminal device may include, for example, but are not limited to: receiving a downlink/sidelink signal, and/or sending an uplink/sidelink signal.

With reference to the communication system shown in FIG. 1, the following describes in detail a data transmission method provided in embodiments of this application.

To better understand the solutions provided in embodiments of this application, the following first describes some terms, concepts, or procedures in embodiments of this application.

Physical-layer data is first described. In this application, the physical-layer data may be native data generated by a physical layer. For example, the physical-layer data may be data generated by listening to a radio channel, or model or training data generated to implement a physical layer module based on artificial intelligence (Artificial Intelligence, AI). For example, the physical-layer data includes but is not limited to sensing data, imaging data, point cloud data, and AI model data.

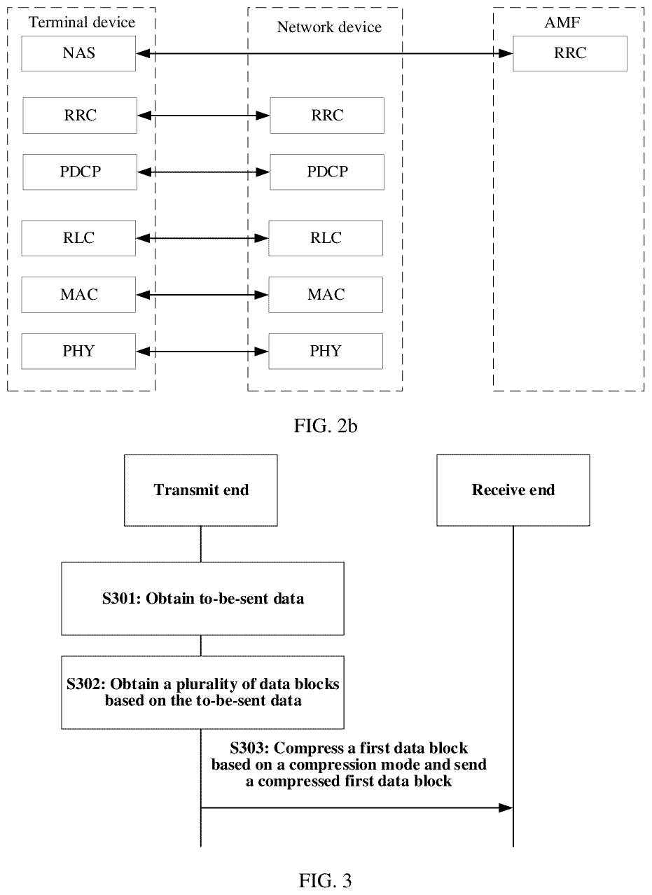

As shown in FIG. 2a, a user plane protocol stack for communication between a terminal device and a network device includes a service data adaptation (service data adaptation protocol, SDAP) layer, a PDCP layer, an RLC layer, a MAC layer, and a PHY layer.

As shown in FIG. 2b, a control plane protocol stack for communication between a terminal device and a network device includes a non-access stratum (non-access stratum, NAS), an RRC layer, a PDCP layer, an RLC layer, a MAC layer, and a PHY layer.

It may be understood that the physical-layer data in this application may include data in a communication scenario between the terminal device and the network device, for example, native data at a physical layer of the terminal device and/or native data at a physical layer of the network device. In addition, the physical-layer data may include data in a communication scenario between UEs, for example, sensing data.

In this application, the terminal device may send uplink data to the network device. The uplink data herein includes but is not limited to the physical-layer data.

An uplink data transmission manner is dynamic grant (dynamic grant, DG) (also referred to as a dynamic uplink grant (dynamic UL grant))-based uplink transmission. In this manner, when a terminal has user plane data to be sent to a base station, the terminal may monitor DCI delivered by the base station over a physical downlink control channel (physical downlink control channel, PDCCH). The DCI includes an uplink grant (uplink grant, UL grant). The uplink grant may be used to authorize the terminal to send the uplink data on a specified time-frequency resource by using a specified parameter, for example, a specified modulation and coding scheme (modulation and coding scheme, MCS). Before monitoring the DCI, the terminal may first send a scheduling request (scheduling request, SR) to the base station over a physical uplink control channel (physical uplink control channel, PUCCH) or report a buffer state (buffer state, BS) to the base station over a physical uplink shared channel (physical uplink shared channel, PUSCH), to notify the base station of an uplink sending requirement or the buffer state. This helps the base station perform the uplink grant and resource scheduling based on the requirement.

The terminal device may monitor the PDCCH based on a PDCCH configuration to obtain the DCI. The PDCCH configuration may include a control resource set (control resource set, CORESET) configuration, a search space (search space) configuration, a radio network temporary identifier (radio network temporary identifier, RNTI) configuration for scrambling/descrambling the PDCCH, a signaling format (format) configuration, or another configuration for PDCCH detection.

A time-frequency resource used for DCI transmission belongs to a configured control resource set (control resource set, CORESET), and the terminal device may detect a candidate time-frequency resource location in the CORESET to receive the DCI.

It may be understood that the uplink data transmission manner provided in embodiments of this application may further include data transmission in a random access (random access, RA) process or grant-free (grant-free, GF) data transmission. This is not specifically limited.

Based on a similar principle, the network device in this application may send downlink data to the terminal device. The downlink data herein includes but is not limited to the physical-layer data. Generally, a downlink data communication process is as follows: The network device sends a PDCCH, where the PDCCH includes scheduling information (such as DCI) for a physical downlink shared channel (physical downlink shared channel, PDSCH), the scheduling information for the PDSCH includes, for example, information such as a time-frequency resource of the PDSCH, and the PDSCH carries downlink data sent by a base station to a UE. The UE receives the downlink data from the network device based on scheduling information in the PDCCH.

For ease of description, data in the following may include the uplink data or the downlink data. In addition, the uplink data in this application may also be replaced with the downlink data. For example, “sending the uplink data” and “receiving the downlink data” may be replaced with each other, and “sending the downlink data” and “receiving the uplink data” may be replaced with each other.

Optionally, the technical solutions provided in embodiments of this application may also be applied to sidelink (sidelink, SL) communication. In the communication, one terminal device can initiate paging or access to another terminal device. For example, the technical solutions provided in embodiments of this application may be applied to a device-to-device (device-to-device, D2D) communication scenario, which, for example, may be an NR D2D communication scenario and/or an LTE D2D communication scenario; may be applied to a vehicle-to-everything (vehicle-to-everything, V2X) communication scenario, which, for example, may be an NR V2X communication scenario, an LTE V2X communication scenario, an internet of vehicles communication scenario, and/or a vehicle-to-vehicle (vehicle-to-vehicle, V2V) communication scenario; or may be used in fields such as intelligent driving and intelligent connected vehicles. Therefore, the data in this application may further include data in a sidelink communication scenario.

In a current data transmission process, a transmit end usually needs to compress to-be-sent original data, perform channel coding on compressed data, and then send the compressed data through a radio channel. Accordingly, a receive end may receive the compressed data that is transmitted on the radio channel and on which channel coding is performed, and restore the original data based on the compressed data. The transmit end is, for example, a terminal device in an uplink data sending process or a sidelink communication scenario or a network device in a downlink data sending process, and the receive end is, for example, a network device in the uplink data sending process or a terminal device in the downlink data sending process or the sidelink communication scenario. In this application, unless otherwise specified, the transmit end is a transmit end of to-be-sent data, and the receive end is a receive end of the to-be-sent data.

Using the physical-layer data as an example, because collection of a plurality of broadband frequencies and electromagnetic signals in different directions is involved, and a large amount of physical-layer data such as sensing data and imaging data is obtained, a compression operation needs to be performed before wireless backhaul is performed, to reduce consumption of wireless transmission resources. However, the physical-layer data has characteristics of a large data amount and complex data. When the physical-layer data is compressed in an existing data compression mode, a problem of low compression efficiency exists. In addition, a transmission error may occur in signal receiving, causing incorrect transmission and a severe performance loss during data decompression and reconstruction, resulting in a reduction in overall data transmission performance.

To improve compression efficiency and transmission robustness of physical-layer data, an embodiment of this application provides a data transmission method. The method may be performed by a transmit end of data and a receive end of the data. It may be understood that the transmit end may be a terminal device or a network device configured to send data, or may be a component in the terminal device or the network device. The component in this application may include, for example, at least one of a chip, a chip system, a processor, a transceiver, a processing unit (or a processing module), or a transceiver unit (or a transceiver module, or a communication module, or a communication unit).

As shown in FIG. 3, a data transmission method provided in an embodiment of this application may include the following steps.

S301: A transmit end obtains to-be-sent data.

Optionally, in S301, the to-be-sent data may include but is not limited to physical-layer data.

It may be understood that, in S301, the transmit end obtains the to-be-sent data, but the to-be-sent data is not limited to physical-layer native data generated by a physical layer of the transmit end. For the physical-layer data, refer to descriptions in this application. In addition, the to-be-sent data obtained by the transmit end may further include data that is obtained by the physical layer and that is from an upper layer, and the data from the upper layer may be, for example, data at an application layer.

S302: The transmit end obtains a plurality of data blocks (data blocks, DBs) based on the to-be-sent data.

In this application, the data block may also be referred to as a data region or a feedback region (feedback region, FB region).

For ease of subsequent description, N may represent a quantity of the plurality of data blocks obtained based on the to-be-sent data, where N is a positive integer greater than 1.

In S302, the transmit end may obtain the plurality of data blocks based on the to-be-sent data in a plurality of manners. Some possible implementations are described herein by using examples, but this does not indicate that the example manners of determining the plurality of data blocks are all implementations.

Manner 1: If the to-be-sent data is two-dimensional data or three-dimensional data, the transmit end may evenly divide the to-be-sent data to obtain the plurality of data blocks. The two-dimensional data is, for example, sensing data and imaging data at the physical layer, and the three-dimensional data is, for example, point cloud data.

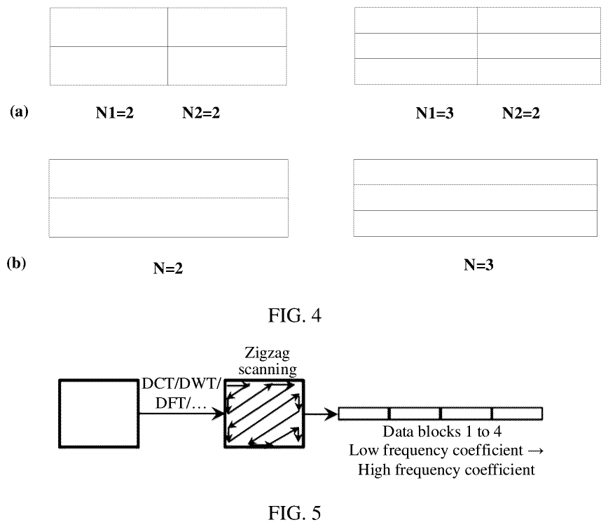

For example, an even division manner of the two-dimensional data is shown in FIG. 4.

As shown in an example shown by a number (a) in FIG. 4, for the two-dimensional data, it may be assumed that N=N1*N2, where both N1 and N2 are positive integers. N1 and N2 each are a quantity of copies into which the two-dimensional data is evenly divided in one dimension of the two-dimensional data, and N1 and N2 correspond to different dimensions. For example, N1 corresponds to a y direction of coordinates of the two-dimensional data, and N2 corresponds to an x direction of the coordinates of the two-dimensional data. In this case, a length of each data block obtained through division in the y direction is 1/N1 of a length in the y direction of the two-dimensional data, and a length of each data block obtained through division in the x direction is 1/N2 of a length in the x direction of the two-dimensional data. Further, optionally, the transmit end and the receive end determine N in a negotiation, pre-configuration, or predefinition manner. The transmit end and the receive end may consider by default that N1 is greater than (or greater than or equal to) N2, and both N1 and N2 are prime numbers. In this case, the transmit end and the receive end may uniquely determine a combination of N1 and N2, to ensure uniqueness. Therefore, values of N1 and N2 do not need to be separately indicated. For example, N=15. According to a condition that N1 is greater than (or greater than or equal to) N2, and both N1 and N2 are prime numbers, it may be uniquely determined that N1=5 and N2=3. In this application, determining through negotiation may mean that the transmit end sends indication information, information, signaling, or a message to the receive end, to indicate a parameter, a value, or information; or determining through negotiation may mean that the receive end sends indication information, information, signaling, or a message to the transmit end, to indicate a parameter, a value, or information. In addition, in this application, the determining through negotiation may be replaced with: being indicated by the transmit end or the receive end, or being indicated by the network device.

In addition, for the two-dimensional data, the data may be evenly divided in a dimension (for example, a length or a width) of the two-dimensional data. As shown in an example shown by a number (b) in FIG. 4, the two-dimensional data is evenly divided based on a width of the two-dimensional data, that is, a length of each data block obtained through division is a length of the two-dimensional data, and a width of each data block obtained through division is 1/N of the two-dimensional data.

It may be understood that, if the to-be-sent data is three-dimensional data, the three-dimensional data may be evenly divided in a similar manner. For example, it may be assumed that N=N1*N2*N3, where N1, N2, and N3 each are a quantity of copies into which the three-dimensional data is evenly divided in one dimension of the three-dimensional data, and N1, N2, and N3 are different dimensions of the three-dimensional data. For example, N1, N2, and N3 respectively correspond to x, y, and z directions of the three-dimensional data. To be specific, a length of each data block obtained through division in the x direction is 1/NI of a length in the x direction of the three-dimensional data, a length of each data block obtained through division in the y direction is 1/N2 of a length in the y direction of the three-dimensional data, and a length of each data block obtained through division in the z direction is 1/N3 of a length in the z direction of the three-dimensional data. Further, optionally, the transmit end and the receive end determine N in a negotiation, pre-configuration, or predefinition manner. The transmit end and the receive end may consider by default that NI is greater than (or greater than or equal to) N2, N2 is greater than (or greater than or equal to) N3, and N1, N2, and N3 are all prime numbers. In this case, the transmit end and the receive end may uniquely determine a combination of N1, N2, and N3, to ensure uniqueness. Therefore, values of N1, N2, and N3 do not need to be separately indicated. For example, N=30. According to a condition that NI is greater than (or greater than or equal to) N2, N2 is greater than (or greater than or equal to) N3, and N1, N2, and N3 are all prime numbers, it may be uniquely determined that N1=5, N2=3, and N3=2.

In addition, the three-dimensional data may alternatively be evenly divided in one of the x, y, and z directions based on N. For example, the even division in the x direction is used as an example. A length of each data block obtained through division in the x direction is 1/N, a length of each data block obtained through division in the y direction is the same as a length of the three-dimensional data in the y direction, and a length of each data block obtained through division in the z direction is the same as a length of the three-dimensional data in the z direction.

It may be understood that the foregoing even division manner is merely an example for description. During actual application, the transmit end may alternatively evenly divide the to-be-sent data in another manner based on a compression requirement. For example, the transmit end may further sample the to-be-sent data at a fixed interval, to obtain the plurality of data blocks.

Optionally, in Manner 1, one or more of N, N1, N2, and N3 may be determined through negotiation by the transmit end or the receive end, or may be determined in a protocol definition, predefinition, or pre-configuration manner.

Manner 2: The transmit end may group the to-be-sent data in a transform domain to obtain the plurality of data blocks.

For example, the transmit end may perform transform such as discrete cosine transform (discrete cosine transform, DCT), discrete wavelet transform (discrete wavelet transform, DWT), or fast Fourier transform (fast Fourier transform, FFT) on the to-be-sent data, and divide transformed data into N segments in an order from a low frequency to a high frequency or from a high frequency to a low frequency, where each segment of data is used as one data block. For example, optionally, the transformed data is evenly divided into N segments in an order from a low frequency to a high frequency or from a high frequency to a low frequency, to reduce complexity of a processing and indication process.

It may be understood that the DCT may include two-dimensional DCT, for transforming the two-dimensional data. The DCT may further include three-dimensional DCT, for transforming the three-dimensional data.

If the to-be-sent data is two-dimensional data, as shown in FIG. 5, the transmit end may transform the to-be-sent data, obtain one-dimensional data from a low frequency to a high frequency in a two-dimensional zigzag scanning manner, and then divide the one-dimensional data into N segments of data, to obtain N data blocks. Similarly, if the to-be-sent data is three-dimensional data, the transmit end may transform the to-be-sent data, obtain one-dimensional data from a low frequency to a high frequency in a three-dimensional zigzag scanning manner, and then divide the one-dimensional data into N segments of data, to obtain N data blocks.

Optionally, in Manner 2, a value of N and/or a change manner may be determined through negotiation by the transmit end or the receive end, or may be determined in a protocol definition, predefinition, or pre-configuration manner.

Manner 3: The transmit end divides the to-be-sent data into a plurality of data segments, and then obtains the plurality of data blocks based on the plurality of data segments and based on a proportion of data that is in the plurality of data segments and whose value is a specific value.

Optionally, Manner 3 is applicable to a case in which the to-be-sent data includes data whose value is 0 or 1. Therefore, Manner 3 may also be referred to as a binary graph method. In addition, the to-be-sent data in Manner 3 may be one-dimensional data, two-dimensional data, or three-dimensional data.

As shown in FIG. 6, the transmit end may divide, based on a segment size Ns, the one-dimensional data or one-dimensional data obtained by flattening the two-dimensional data or the three-dimensional data into a plurality of data segments Seg i, where i=1, 2, . . . , B, B is a positive integer, and Ns may be a length or a data amount of each data segment. The transmit end may further determine a proportion pᵢ of data that is in each data segment and whose value is a specific value (for example, 0 or 1), and then combine, into a data block, data segments with similar proportions of data whose value is the specific value. For example, a proportion of data that is in a data segment 01001011 and whose value is 0 and a proportion of data that is in a data segment 01001011 and whose value is 1 are 50% respectively.

Optionally, 2^{Q} proportion distribution ranges may be defined. For example, the proportion distribution ranges are denoted as [0, P₁], (P₁, P₂] . . . , (P₂_{^{Q}}₋₂, P₂_{^{Q}}₋₁], (P₂_{^{Q}}₋₁, 1], and these proportion distribution ranges respectively correspond to 2^{Q} data blocks. For example, when Q=2, a maximum of four data blocks may be obtained through division. When some proportion ranges do not correspond to data segments, it is not excluded that a quantity of data blocks obtained by the transmit end is less than 2^{Q}. Optionally, a width of each distribution range (that is, a difference between boundary values of the distribution range) is 1/(2^{Q})^{th}, for example, P₁=1/(2^{Q}). Optionally, widths of any two distribution ranges may alternatively be different. For example, a width of each distribution range may be determined through negotiation, or may be determined through pre-configuration or predefinition. In FIG. 6, each data segment may correspond to one proportion distribution range in [0, P₁], (P₁, P₂], . . . , (P₂_{^{Q}}₋₂, P₂_{^{Q}}₋₁], (P₂_{^{Q}}₋₁, 1]. An example in which a specific value is 1 is used. The transmit end may determine a 1^{st} data block based on a data segment in which a proportion of data whose value is 1 belongs to [0, P₁]. For example, in FIG. 6, a data block 1 corresponds to a data segment (for example, data blocks Seg 1 and Seg B-1) in which a proportion of data whose value is 1 belongs to [0, P₁], a data block 2 corresponds to a data segment (for example, data blocks Seg 3 and Seg B-2) in which a proportion of data whose value is 1 belongs to (P₁, P₂], and a data block 2^{Q} corresponds to a data segment (for example, data blocks Seg 2 and Seg B) in which a proportion of data whose value is 1 belongs to (P₂_{^{Q}}₋₁, 1].

In Manner 3, a quantity of data segments corresponding to a specific proportion distribution range may be 0, that is, the data segment may be empty, in other words, N is less than or equal to 2^{Q}. Therefore, the transmit end needs to send, to the receive end, a number of the data block to which the data segment belongs, so that the receive end restores the to-be-sent data based on the data block.

Optionally, in Manner 3, a value of N, a value of Q), a value of the specific value, and the width of the proportion distribution range may be determined through negotiation by the transmit end or the receive end, or may be determined in a protocol definition, predefinition, or pre-configuration manner.

Manner 4: The transmit end determines the plurality of data blocks based on sparsity of the to-be-sent data.

Manner 4 is applicable to a scenario in which the to-be-sent data is two-dimensional or three-dimensional point cloud data.

In Manner 4, the transmit end may use, based on the sparsity of the to-be-sent data, data in a coordinate range with high data density (for example, a small proportion of data whose value is 0) as a data block. If data in a specific coordinate range is sparse (for example, corresponding values are all 0), the data in the range is not mapped to the data block, to reduce overheads.

It may be understood that, in Manner 4, the transmit end may indicate, to the receive end, a coordinate range corresponding to the data block. For example, the transmit end may indicate, by using a two-dimensional coordinate range or a three-dimensional coordinate range, a coordinate range corresponding to the data block, or may indicate, by using at least one of coordinates, a range radius, a diameter, a range length, a width, or a height, a coordinate range corresponding to the data block. It may be further understood that at least one of the range radius, the diameter, the range length, the width, or the height may be pre-configured or predefined. Therefore, the transmit end and the receive end do not need to determine at least one of the range radius, the diameter, the range length, the width, or the height through negotiation, to reduce signaling overheads.

Manner 5: For data of an AI model, the transmit end may determine the plurality of data blocks based on a network layer of the AI model.

For example, data of one network layer or a plurality of adjacent network layers is used as data in one data block. Therefore, data in each data block is more likely to have a similar feature, facilitating improvement of compression efficiency and further facilitating storage.

Optionally, in Manner 5, the transmit end may indicate a mapping relationship between the data block and the network layer of the AI model to the network device, so that the receive end restores the data of the AI model.

Optionally, the transmit end may number the data blocks. For example, when N=4, numbers of the data blocks are 1, 2, 3, and 4 respectively.

S303: The transmit end compresses the first data block based on a compression mode and sends a compressed first data block.

The first data block is one of the plurality of data blocks obtained based on the to-be-sent data. Accordingly, the receive end may receive the compressed first data block. The receive end may further determine a compression mode of the first data block, and decompress the first data block based on the compression mode of the first data block, to obtain the first data block. It may be understood that the receive end may restore the to-be-sent data based on the plurality of data blocks including the first data block. It should be understood that, for the receive end, restored data is referred to as “to-be-sent data” indicating that the data restored based on the plurality of data blocks is the same as the to-be-sent data of the transmit end, and not necessarily indicating that the data needs to be sent by the receive end.

Based on the procedure shown in FIG. 3, block compression and transmission may be performed on the to-be-sent data. Compression modes of different data blocks obtained based on the to-be-sent data may be the same or different. This is not specifically limited. Therefore, the compression mode is more flexible, and different compression modes can be used for different data, to meet a compression requirement of complex data such as the physical-layer data, so as to improve compression efficiency.

The compression mode in S303 may also be referred to as the compression mode of the first data block.

The compression mode of the first data block may include independent compression or reference compression. The independent compression means that other data or another data block is not referenced in a compression process of a data block. The reference compression means that, to achieve a better compression effect, for example, to improve a compression rate, a data block that currently needs to be compressed is compressed with reference to a previous data block.

Optionally, the previous data block is a data block that is received successfully (or decompressed successfully) by the receive end. The transmit end may determine, based on feedback information from the receive end, whether the receive end receives the data block successfully. For example, when the feedback information indicates that the data block is not received successfully, or the transmit end does not receive the feedback information, the transmit end may determine that the receive end does not receive the data block successfully.

In a possible implementation, the feedback information herein may indicate whether the data block is received successfully. For example, the feedback information may be hybrid automatic repeat request (hybrid automatic repeat request, HARQ) information, and the HARQ information may include HARQ acknowledgement (acknowledgement, ACK) information or HARQ negative acknowledgement (negative acknowledgement, NACK) information. A HARQ ACK indicates that the receive end receives the data block successfully, and a HARQ NACK may indicate that the receive end does not receive the data block successfully. In addition, the feedback information may alternatively be N-bit indication information (which may be referred to as feedback indication information subsequently) corresponding to the data block. Each bit may indicate, by using a value of 0 or 1, whether the receive end successfully receives the data block corresponding to the bit. For example, 0 indicates that the data block is incorrectly transmitted and cannot be correctly decompressed, and 1 indicates that the data block is correctly transmitted and can be correctly decompressed. For example, if N=4, indication information 1101 indicates that in four data blocks, data blocks numbered 1, 2, and 4 are received by the receive end successfully, and a data block numbered 3 is not received by the receive end successfully.

Optionally, the feedback information indicating whether the data block is received successfully may be carried in control information. For example, for downlink data, the feedback information may be carried in uplink control information (uplink control information, UCI). Further, optionally, the UCI may include a newly defined UCI format (format).

In another possible implementation, the feedback information may indicate whether a transmission unit is received successfully. If the transmission unit is received successfully, it indicates that a data block occupying the transmission unit is received successfully. Otherwise, if the feedback information indicates that the transmission unit is not received successfully, it indicates that a data block occupying the transmission unit is not received successfully. In this application, the transmission unit may be a transport block (transport block, TB), a combination of a plurality of TBs, a code block (code block, CB), a code block group (code block group, CBG), a combination of a plurality of CBs or CBGs, or the like. This is not specifically limited. One TB may include a plurality of CBs or at least one CBG, and one CBG may include at least one CB.

The foregoing implementation of the feedback information is merely an example for description. This is not specifically limited.

Optionally, the reference compression may be determined based on at least one of a historical feedback result of the data block, a feedback delay d, and first duration d_{ref}. The first duration is a maximum distance between a transmission time point of the previous data block and a transmission time point of the to-be-compressed first data block. The feedback delay is a minimum delay between time when the transmit end sends a data block and time when feedback information is received from the receive end. The feedback information is used for determining whether the receive end receives the data block successfully. The delay is generally related to a distance between the transmit end and the receive end, receiving performance of the receive end, and uplink and downlink resource scheduling. Therefore, if the transmission time point of the first data block is t, a sending time point of reference data is within a time point range of [t-d_{ref}, t-d]. d_{ref}>d.

In a possible example, if there is no successfully received data block between a time point t-d_{ref} and a time point t, the transmit end compresses a first data packet in an independent compression mode.

Optionally, d_{ref} and/or d in this application are/is at least one slot, at least one subframe, or at least one orthogonal frequency division multiplexing (orthogonal frequency division multiplexing, OFDM) symbol, or may be a combination of at least two of at least one slot, at least one subframe, or at least one symbol. It may be understood that the OFDM symbol in this application may be referred to as a symbol.

Optionally, the reference compression may include reference compression based on nearest neighbor selection and reference compression based on optimal compression efficiency.

The reference compression based on nearest neighbor selection means that a data block whose transmission time point is closest to the transmission time point of the first data block is selected as a previous data block, and the previous data block is a successfully received data block, and the first data block is compressed based on the previous data block. For example, if a time point at which the first data block is compressed (or a sending time point of the first data block) is t, a reference data block is a successfully received data block that is before the first data block and that is closest to the time point t.

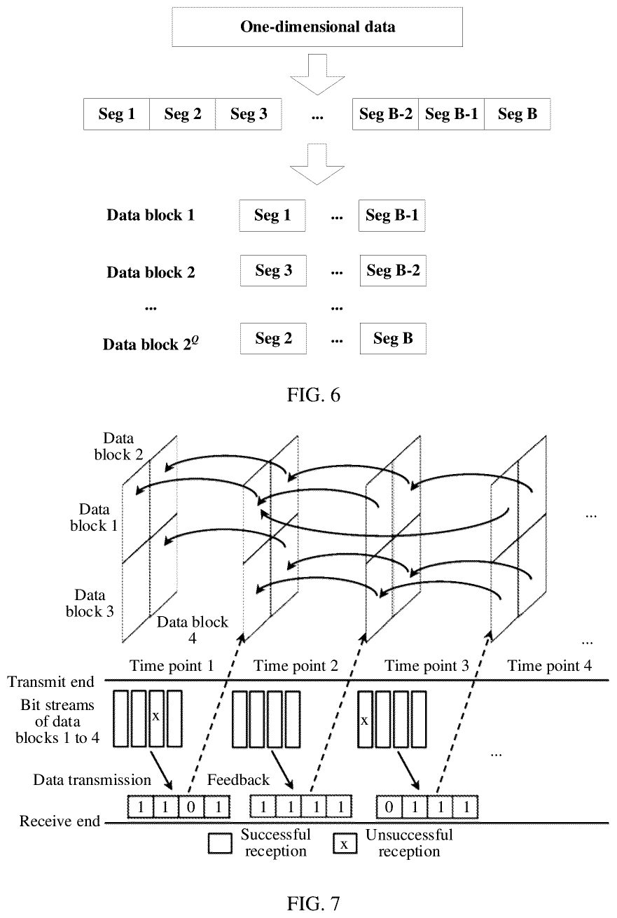

For example, as shown in FIG. 7, to-be-sent data whose transmission time point is a time point 2 corresponds to four data blocks, and feedback indication information of the four data blocks is 1111. To-be-sent data whose transmission time point is a time point 3 corresponds to four data blocks, and feedback indication information of the four data blocks is 0111. A value of the feedback indication information is 1, indicating that the receive end receives corresponding data successfully, and a value is 0, indicating that the receive end does not receive corresponding data correctly. To-be-sent data whose transmission time point is a time point 4 corresponds to four data blocks. When the reference compression based on nearest neighbor selection is used, in the four data blocks, data blocks numbered 2, 3, and 4 may be compressed with reference to data blocks that are numbered 2, 3, and 4 and whose transmission time points are the time point 3, and a data block numbered 1 may be compressed with reference to a data block that is numbered 1 and whose transmission time point is the time point 2. In addition, in FIG. 7, if an interval between a time point 1 and the time point 4 exceeds a first time point when the data block whose transmission time point is the time point 4 is determined, a feedback result of the data block at the time point 1 may not be considered (or may be ignored). For example, an arrow direction in FIG. 7 represents an online data block that is referenced in data block compression.

The reference compression based on optimal compression efficiency means that the transmit end compresses the first data block with reference to a previous data block that enables the first data block to have a highest compression rate. In the compression mode, the transmit end may determine, based on the time point range of [t-d_{ref}, t-d], at least one data block correctly received within the time point range, and determine, as a previous data block from the at least one data block, a data block that enables the first data block to have a highest compression rate. For example, the transmit end may determine a plurality of correctly received data blocks in a plurality of time point ranges of [t-d_{ref}, t-d], separately determine compression rates of the first data block when these data blocks are referenced, select, as a previous data block, a data block that enables the first data block to have a highest compression rate, and compress the first data block with reference to the previous data block.

Still using FIG. 7 as an example, the transmit end may compress, with reference to the data block numbered 1 at the time point 2, the data block numbered 1 at the time point 4, compress, with reference to the data block numbered 2 at the time point 2 or the time point 3, the data block numbered 2 at the time point 4, and compress, with reference to the data block numbered 3 at the time point 2 or the time point 3, the data block numbered 3 at the time point 4, and compress, with reference to the data block numbered 4 at the time point 2 or the time point 3, the data block numbered 4 at the time point 4. The data block numbered 2 is used as an example. If a compression rate of the data block numbered 2 at the time point 4 that is compressed with reference to the data block numbered 2 at the time point 2 is higher than a compression rate of the data block numbered 2 at the time point 4 that is compressed with reference to the data block numbered 2 at the time point 3, the data block numbered 2 at the time point 4 may be compressed with reference to the data block numbered 2 at the time point 2. If a compression rate of the data block numbered 2 at the time point 4 that is compressed with reference to the data block numbered 2 at the time point 3 is higher than (or not lower than) a compression rate of the data block numbered 2 at the time point 4 that is compressed with reference to the data block numbered 2 at the time point 2, the data block numbered 2 at the time point 4 may be compressed with reference to the data block numbered 2 at the time point 3.

It may be understood that the compression mode, namely, the reference compression may be determined through negotiation between the transmit end and the receive end, or may be pre-configured or predefined. For example, the compression mode of the reference compression may be indicated by the network device to the terminal device.

Optionally, when determining that the reference compression based on nearest neighbor selection is used for the first data block, the receive end may determine, based on previously sent feedback information or a receiving result of a data block corresponding to the feedback information, a previous data block referenced for the first data block, so that the receive end can decompress the first data block with reference to a data block corresponding to the transmission time point, to improve decompression efficiency and a success rate.

In this application, optionally, the receive end and/or the transmit end may store the receiving result of the data block, for example, maintain a data block status list. The list may be used by the receive end and/or the transmit end to determine a previous data block that may be referenced in the reference compression, to improve compression and/or decompression efficiency. The data block status list may indicate mapping relationships between a transmission time point of a data block, a number of the data block, and a receiving status of the data block. The receiving status may indicate whether the receive end receives the data block successfully. For example, if the receive end receives one data block successfully, a receiving status corresponding to the data block may be represented by a value 1 in the data block status list. If the receive end does not receive one data block successfully, a receiving status corresponding to the data block is represented by a value 0. Optionally, a range of transmission time points of data blocks in the data block status list is [t-d_{ref}, t-d].

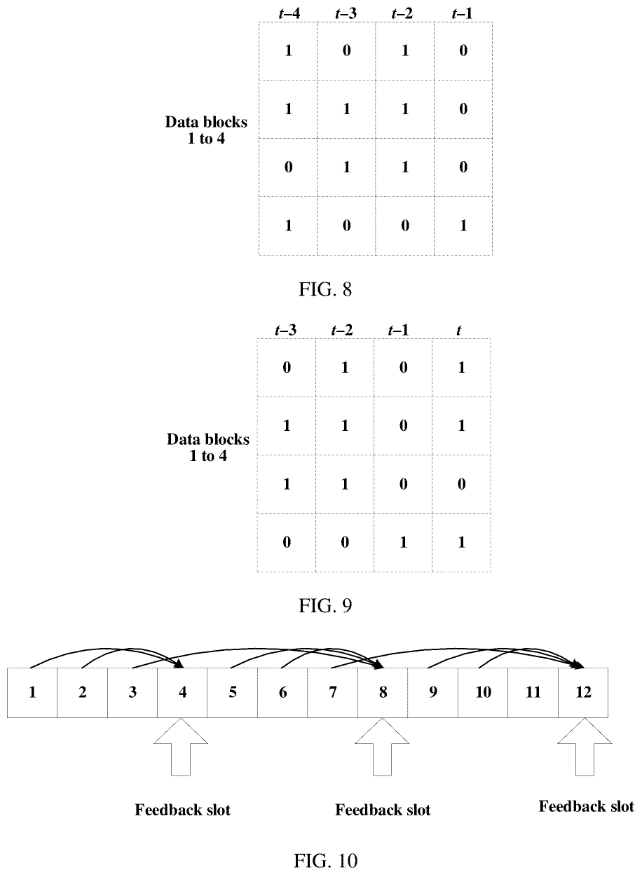

For example, the data block status list is shown in FIG. 8 and/or FIG. 9.

For example, a current time point is t, d=1, and d_{ref}=3. Transmission time points of data blocks in the data block status list shown in FIG. 8 are t−4, t−3, t−2, and t−1 respectively. t−1 represents a transmission time point of a latest data block before the t, t−2 represents a transmission time point of a penultimate data block before the time point t, and so on. For example, there may be at least one slot, at least one subframe, at least one symbol, or a combination of at least two of at least one slot, at least one subframe, or at least one symbol between the time point/and the time point t−1 (or the other two time points in a similar case). This is not specifically limited. Optionally, the transmit end and the receive end may determine an interval length between the time point/and the time point t−1 through negotiation, or may determine the interval length through predefinition or pre-configuration, or in another manner. It can be learned that, in FIG. 8, a quantity N of data blocks is 4.

In addition, with the passage of time, a receiving status of a new data block is recorded based on the data block status list shown in FIG. 8, and the receive end and/or the transmit end may store an updated data block status list shown in FIG. 9. A range of transmission time points of data blocks in FIG. 9 is [t-d_{ref}+1, t-d+1]. It can be learned that, compared with FIG. 8, the receiving status of the data block at the time point/is updated in FIG. 9, that is, transmission time points of the data blocks shown in FIG. 9 are t−3, t−2, t−1, and/respectively. It may be understood that, the data block status list shown in FIG. 9 may be used to determine a previous data block that may be referenced in reference compression of a data block at a time point t+1.

It may be understood that, if the reference compression based on nearest neighbor selection is used, based on the data block status list shown in FIG. 8, the transmit end may separately compress, with reference to data blocks numbered 1 to 3 at the time point t−2, data blocks numbered 1 to 3 at the t, and may compress, with reference to a data block numbered 4 at the time point t−1, a data block numbered 4 at the time point t. In addition, based on the data block status list shown in FIG. 9, the transmit end may separately compress, with reference to the data blocks numbered 1, 2, and 4 at the time point t, data blocks numbered 1, 2, and 4 at the t+1, and may compress, with reference to a data block numbered 3 at the t−2, a data block numbered 3 at the t+1. Similarly, the receive end may correctly determine, based on the data block status list, a previous data block referenced in the reference compression.

Optionally, if the first data block is compressed in the reference compression mode with reference to a previous data block, the transmit end may further send a transmission time point (for example, a timestamp) of the previous data block to the receive end, so that the receive end can decompress the first data block with reference to a data block corresponding to the transmission time point, to improve decompression efficiency and a success rate.

For example, the transmit end indicates a number or an index of the previous data block by using the indication information. Alternatively, the indication information may include the transmission time point of the data block, and a value range is [1, d_{ref}-d+1], respectively representing a time point t-d to a time point t-d_{ref} in a chronological order.

Optionally, in this application, the transmit end may compress the data block in the independent compression mode based on a specific period. For example, the transmit end compresses, in each period, a data block of a 1^{st} piece of to-be-sent data in the independent compression mode, and performs reference compression on subsequent data (a 2^{nd} piece of to-be-sent data and subsequent to-be-sent data) in each period.

Optionally, the period may be determined through negotiation between the transmit end and the receive end, or may be pre-configured or predefined. For example, the period may be indicated by the network device to the terminal device.

In an example, when a value of the period Tis infinite, it indicates that using the independent compression mode for compression is not restored; and when a value of the period T is 0, it indicates that the reference compression is not used, in other words, it indicates that the independent compression is always used.

Optionally, the transmit end may send compression mode information to the receive end, to indicate the compression mode of the first data block.

For example, compression modes such as the independent compression and the reference compression may correspond to different indexes (indexes), and the compression mode information may include the index corresponding to the compression mode.

In an example, when a specific reference compression mode is used by default, the compression mode information of the first data block may be included in a bitmap (bitmap). For example, for a bit in the bitmap, a value 0 or 1 of the bit indicates that the independent compression and the reference compression are used respectively. The bitmap may include values of a plurality of bits, and a value of each bit (or a combination of the plurality of bits) may indicate a compression mode of one data block. For example, the reference compression based on nearest neighbor selection is used as an example. A bitmap of 0111 may indicate that the independent compression is used for a data block numbered 1, and indicate that the reference compression based on nearest neighbor selection is used for data blocks numbered 2 to 4. It may be understood that, if the reference compression is the reference compression based on optimal compression efficiency, an additional field may be used to indicate a transmission time point of a previous data block referenced for compression of the first data block.

In this application, the compression mode information and the transmission time point may be carried in same or different information and/or a same resource or different resources. This is not specifically limited. In other words, the compression mode information and the transmission time point may be sent independently, or may be sent together.

In another example, the compression mode may be indicated by using an index value, where the independent compression corresponds to an index 0, the reference compression based on nearest neighbor selection corresponds to an index 1, and the reference compression based on optimal compression efficiency corresponds to an index 2. If the reference compression based on optimal compression efficiency is used, an additional field may be used to indicate a transmission time point of a previous data block referenced for compression of the first data block. For example, if the reference compression based on optimal compression efficiency is used to compress the first data block, the manner may be indicated by using ceil [log₂(d_{ref}-d+2)] bits. For example, an all-zero sequence represents the independent compression, and a bit sequence corresponding to 1 to d_{ref}-d+1 represents the reference compression.

Using d=1 and d_{ref}=4 as an example, ceil [log₂(d_{ref}-d+2)]=3 bits, 000 represents the independent compression, and 001, 010, 011, and 100 respectively represent four reference time points corresponding to t−1 and t−4. d_{ref}-d+2 may be a plurality of slots, a plurality of subframes, or a plurality of symbols.

In an implementation, the compression mode information may be included in control information corresponding to a data block. In this application, the control information corresponding to the data block may be used as a set of information and parameters related to the data block. A transmission parameter may include at least one of a data block number, a quantity of data blocks (that is, indication information of N), the compression mode information, and information about a mapping relationship between a data block and a transmission unit. Optionally, the control information corresponding to the data block may be carried on a data channel or a control channel. The data channel may be used to transmit the data block, and the control channel may be used to schedule or configure transmission of the data block. If the control information corresponding to the data block is carried on the data channel, one of the optional manners is as follows: The control information is carried in a header (header) of a frame structure in which the data block is located, or the control information is used as a part of data (data) of a frame structure in which the data block is located.

The following describes information about a mapping relationship between a data block and a transmission unit based on different mapping relationships between the data block and the transmission unit. It may be understood that the information about the mapping relationship between the data block and the transmission unit may indicate a transmission unit occupied by the data block.

Case 1: A data block is in one-to-one correspondence with a TB, to be specific, one TB is occupied by only one data block, and the data block does not occupy another TB.

When a data block is in one-to-one correspondence with a TB, the information about the mapping relationship between the data block and the transmission unit may include a mapping relationship between a number of the data block and a TB.

Optionally, if the control information and the data block are mapped to a same TB, the information about the mapping relationship between the data block and the transmission unit may include only the number of the data block, indicating that the TB is used to carry only one data block. As shown in Table 1, when the data block and the control information are carried in a same TB, the control information may include the number of the data block and the compression mode information.

TABLE 1

| | |
|---|---|
| Number of a data block | Compression mode information |

If the control information is transmitted over the control channel, the control information may include the number of the data block, a number of a TB in which the data block is located, and the compression mode information.

Optionally, if a compressed data block in one TB cannot be evenly divided into an integer quantity of CBs, a part of data that is insufficient to form one CB needs to be padded with zeros.

Case 2: One TB corresponds to a plurality of data blocks, that is, one TB is occupied by a plurality of data blocks.

In Case 2, the information about the mapping relationship between the data block and the transmission unit includes a mapping relationship between the data block and a CB or a CBG, for example, includes a number of the data block and a number of the CB or the CBG.

Optionally, in Case 2, the control information may further include information about a quantity of data blocks that occupy one TB.

If the data block corresponds to the CB, the data block needs to be compressed and then aligned with the CB, that is, a part of data that is insufficient to form one CB is padded with zeros. If the data block corresponds to the CBG, the data block needs to be compressed and then aligned with the CBG, that is, a part of data that is insufficient to form one CBG is padded with zeros.

Optionally, in Case 2, the information about the mapping relationship between the data block and the transmission unit may further include indication information indicating whether a data block spans TBs. The information may also be referred to as segment indication information of a start data block and/or an end data block. For example, the information about the mapping relationship between the data block and the transmission unit includes two bits, respectively indicating whether a 1^{st} data block and a last data block in a same TB span different TBs.

In addition, in Case 2, the control information may further include compression mode information of each data block.

For example, when a plurality of data blocks are carried in a same TB, a structure of control information sent on the data channel together with the data blocks is shown in Table 2.

TABLE 2

| | | | | |
|---|---|---|---|---|
| Quantity | Numbers of | Mapping | Indication | Compression mode |
| of data | the data | relationship | information | information of the |
| blocks | blocks | between a data | indicating whether | data blocks |
| | | block and a CB | the data blocks span | |
| | | or a CBG | a TB | |

Case 3: One data block is sent by using a plurality of TBs, or one data block occupies a plurality of TBs.

In Case 3, the information about the mapping relationship between the data block and the transmission unit may include a mapping relationship between a number of the data block and a number of a TB. If the control information and the data block occupy a same TB, the control information may include a number of the data block and an end indication, and the end indication may indicate that the current data is a last segment of data of the data block.

In addition, in Case 3, the control information may further include compression mode information of each data block.

For example, when a plurality of data blocks are carried in a same TB, a structure of control information sent on the data channel together with the data blocks is shown in Table 3.

TABLE 3

| | | |
|---|---|---|
| Numbers of data | Sending end | Compression mode |
| blocks | indication | information of the data blocks |

Optionally, to be compatible with the foregoing Case 1 to Case 3, the control information carried on the data channel may have a structure shown in Table 4.

TABLE 4

| | | | | | |
|---|---|---|---|---|---|
| Quantity | Numbers of | Mapping | Indication | Sending | Compression mode |
| of data | the data | relationship | information | end | information of the |
| blocks | blocks | between a data | indicating | indication | data blocks |
| | | block and a CB | whether the | | |
| | | or a CBG | data blocks | | |
| | | | span a TB | | |

Optionally, the mapping relationship between the data block and the CB or the CBG, the indication information indicating whether the data block spans a TB, and the sending end indication in Table 4 are optional.

In addition, if the control information is carried on the control channel, in an example compatible with the foregoing Case 1 to Case 3, the control information may include a structure shown in Table 5.

TABLE 5

| | | | | | |
|---|---|---|---|---|---|
| Number | Number | Number of a | Number | Number of an | Compression mode |
| of a data | of a start | start CB or | of an end | end CB or | information of the |
| block | TB | CBG occupied | TB | CBG occupied | data block |
| | occupied | by the data | occupied | by the data | |
| | by the | block | by the | block | |
| | data block | | data block | | |

In Table 5, the number of the start TB occupied by the data block and the number of the end TB occupied by the data block are respectively numbers of a 1^{st} TB and a last TB that are occupied by the data block. If only one TB is occupied by the data block, the number of the start TB is the same as the number of the end TB. The number of the start CB or CBG occupied by the data block indicates a number of a 1^{st} CB or CBG occupied by the data block in the start TB. The number of the end CB or CBG occupied by the data block indicates a number of a last CB or CBG occupied by the data block in the end TB. For the number of the data block and the compression mode information of the data block, refer to the foregoing descriptions. Details are not described herein again. It may be understood that the structure shown in Table 5 represents control information corresponding to one data block.

Optionally, the control information shown in Table 5 may be carried in DCI.

In this application, the transmit end may further receive feedback information for the first data block from the receive end, and the feedback information may indicate whether the receive end receives the first data block successfully. Optionally, a time interval between a transmission time point of the feedback information for the first data block and the transmission time point of the first data block is not less than k time units, and m is a positive integer. In this application, the time unit may be a slot, a subframe, a symbol, a plurality of slots, a plurality of subframes, a plurality of symbols, or a combination of at least two of at least one slot, at least one subframe, or at least one symbol.

An example in which the time unit is a slot is used. As shown in FIG. 10, the first data block is carried in a slot 3, and a slot 4, a slot 8, and a slot 12 may be used to carry the feedback information. Because there is one slot between the slot 3 in which the first data block is located and the slot 4, and in some cases, the receive end needs to reserve sufficient processing time for decoding, the feedback information corresponding to the first data block may be carried in the slot 8 or the slot 12, but not carried in the slot 4. It may also be understood that a transmission time point of feedback information corresponding to data blocks of X TBs carried in an (n−m)^{th} slot to an (n+k−m)^{th} slot is an (n+k)^{th} slot, where both n and X are positive integers, and m is a nonnegative integer. Optionally, a value of m is determined based on a capability of a UE or a scenario (for example, corresponding to a data processing delay). In addition, in this example, a quantity of bits of each set of feedback information does not exceed X*N, where X is a quantity of TBs in each feedback period, a quantity of data blocks transmitted in each TB does not exceed N, and N is a quantity of data blocks determined based on the to-be-transmitted data.

Optionally, k may be a value determined through negotiation between the transmit end and the receive end, or may be a value determined through pre-configuration or predefinition.

It may be understood that the feedback period in the example shown in FIG. 10 is four slots. In this application, the feedback period of the feedback information may be a value determined through negotiation between the transmit end and the receive end, or may be a value determined through pre-configuration or predefinition. The transmit end and/or the receive end may change a feedback frequency by adjusting the feedback period.

With reference to the foregoing descriptions, the feedback information of the first data block may include information indicating whether the first data block is received successfully, or may include information indicating whether the transmission unit occupied by the first data block is received successfully.

Table 6 shows a format of the feedback information according to an embodiment of this application. In this format, an ACK/NACK field may indicate whether the receive end receives each data block successfully. A multi-time-point switch may indicate whether a data block corresponding to current feedback information is from data at a time point (for example, a transmission time point or a generation time point). If the data block corresponding to the current feedback information is from the data at the time point, a value of the multi-time-point switch is 0 (which may alternatively be 1). In this case, a timestamp field may include one timestamp to indicate time points of a plurality of data blocks. If the data block corresponding to the current feedback information is not from the data at the time point, a value of the multi-time-point switch is 1 (which may alternatively be 0). In this case, a timestamp field may include timestamps of a plurality of data blocks.

TABLE 6

| | | | | |
|---|---|---|---|---|
| Quantity of | Numbers of | ACK/NACK | Multi-time- | Timestamp |
| data blocks | the data blocks | | point switch | |

Optionally, based on the feedback information shown in Table 6, when a static mode is used, although there is a lost data block, the lost data block needs to be fed back in the feedback information. For example, a NACK indicates that the data block is not received successfully. When a dynamic mode is used, because the feedback information includes a timestamp, an ACK/NACK of the lost data block may not be fed back, that is, the quantity of data blocks and the numbers of the data blocks may not include information about the lost data block. Whether the static mode or the dynamic mode is specifically used for indication may be determined by the receive end and the transmit end through negotiation, or may be determined in a pre-configuration or predefinition manner.

Optionally, the feedback information shown in Table 6 may be carried in DCI.

In addition, optionally, the feedback information may alternatively be carried in a MAC control element (control element, CE).

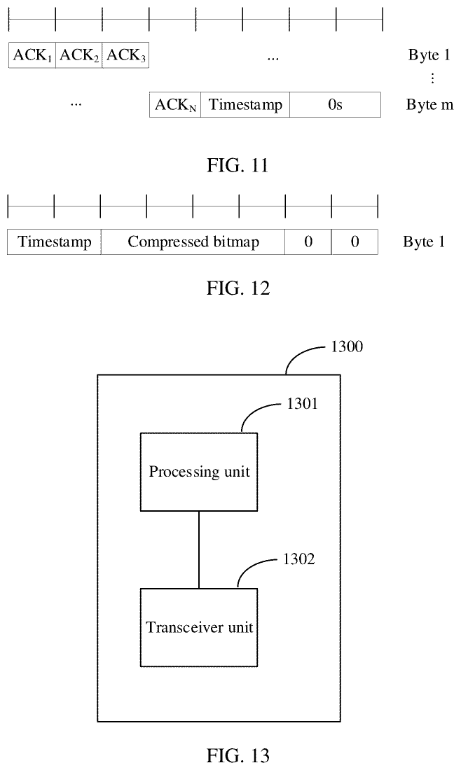

As shown in FIG. 11, a possible implementation in which the feedback information is carried in the MAC CE is used. A length of a bit of the bitmap (for example, an ACK₁, an ACK₂, an ACK₃, . . . , and an ACK_{N}) is consistent with a quantity N of data blocks, and each bit in the bitmap indicates whether a corresponding data block is received successfully. In addition, the feedback information further includes a timestamp (such as a transmission time point) of the data block, and a part that is insufficient to form a byte (byte) is padded with zeros.

As shown in FIG. 12, another possible implementation in which the feedback information is carried in the MAC CE is used. For example, in a tree compression mode (which is similar to entropy coding, where the entropy coding is applicable to a case in which a bit corresponding to a bitmap is large), several optional MAC CE lengths, such as 8, 16, 24, and 32, may be defined, and a MAC CE length is selected based on a sum of a timestamp length and a length obtained through bitmap compression. Accordingly, a receive end (that is, a transmit end of the data) of the feedback information ends decoding in a tree compression order, and 0 at a tail is automatically removed.

In addition, optionally, feedback information at a plurality of time points may be aggregated into one MAC CE for sending, so that feedback information of data blocks at different time points may be flexibly aggregated. In one manner, original bitmaps at the plurality of time points are connected to the timestamps end by end. In another manner, only a timestamp and a number of a successfully received data block are fed back.

In this application, the transmit end may retransmit the data block when determining that the receive end does not receive the data block successfully. If the transmit end does not receive the feedback information of the data block within specific duration, or the feedback information of the data block is a NACK, the transmit end determines that the receive end does not receive the data block successfully.

For example, the network device may schedule, by using the DCI, the terminal device to retransmit the data block. The DCI may indicate a quantity of retransmissions and a retransmission resource, and the terminal device retransmits the data block on the retransmission resource based on the quantity of retransmissions. Optionally, the DCI may further include a timestamp of a data block that needs to be retransmitted, and the timestamp indicates, for example, a transmission time point of the data block.

Optionally, in this application, to avoid a case in which transmission performance of initially transmitted data is reduced due to an excessively large quantity of retransmissions of the data block, the transmit end may end retransmission in advance. For example, the transmit end may send third information to the receive end, where the third information indicates to stop retransmitting a data block (for example, the first data block).

In an example, when an interval between transmission time points of any two retransmitted first data blocks exceeds a threshold, the transmit end may send the third information. For example, the threshold is the first duration d_{ref} or the feedback delay d. Alternatively, the threshold may be determined based on the first duration d_{ref} and the feedback delay d. For example, the threshold is d_{ref}-d.

The third information may be a field in the DCI. When a value of the field is a specific value, it indicates that retransmission of the first data block is stopped. For example, one bit is used as the field. When a value of the bit is 1, it indicates that the retransmission of the data block does not need to be stopped. When a value of the bit is 0, it indicates that the retransmission of the data block is stopped.

In addition, optionally, the third information may include a new data indicator (new data indicator, NDI) in the DCI.

In an example, when the retransmission of the first data block needs to be ended in advance, although the receive end does not receive the first data block successfully, a value of the NDI is still flipped, to indicate that the first data block does not need to be retransmitted again, so that more transmission resources are used for initial transmission.

In another example, when the retransmission of the first data block needs to be ended in advance, a value of the NDI is not flipped, and a bit (or a field) in the DCI indicates to stop retransmitting the first data block. The bit (or the field) may be used as the third information. It may be understood that a function of the NDI in this example remains unchanged, that is, if the NDI is flipped, it indicates that data is received successfully, and if the NDI is not flipped, it indicates that the data is not received successfully.

In another example, when the DCI includes the NDI and the third information, the third information may alternatively indicate whether TB data corresponding to the data block is received successfully, and a value of the NDI is flipped or remains unchanged, to indicate whether retransmission needs to be ended. For example, when a value of the third information is 0, it indicates that the data is not received successfully, and when a value of the third information is 1, it indicates that the data is received successfully. When the retransmission of the first data block needs to be ended in advance, a value of the NDI is flipped, and a value of the third information is 0. In this case, NDI flipping indicates that the retransmission of the first data block is stopped, and the value of the third information indicates that the data is not received successfully.

The foregoing describes the method provided in embodiments of this application. To implement the functions in the method provided in embodiments of this application, a data transmission apparatus (or may be referred to as a communication apparatus) provided in an embodiment of this application may include a hardware structure and/or a software module, and implement the foregoing functions in a form of the hardware structure, the software module, or a combination of the hardware structure and the software module. Whether a function in the foregoing functions is performed by using the hardware structure, the software module, or the combination of the hardware structure and the software module depends on particular applications and design constraints of the technical solutions. For example, the data transmission apparatus provided in this application may include the network device and/or the terminal device shown in FIG. 1.

As shown in FIG. 13, based on a same technical concept, an embodiment of this application further provides a communication apparatus 1300. The communication apparatus 1300 may be a data transmission apparatus, a component in the data transmission apparatus, or an apparatus that can be used in a matching manner with the data transmission apparatus. The data transmission apparatus may be a terminal device or a network device. In a design, the communication apparatus 1300 may include modules that perform and that are in one-to-one correspondence with the method/operations/steps/actions in the foregoing method embodiment. The module may be a hardware circuit, or may be software, or may be implemented by a hardware circuit in combination with software. In a design, the communication apparatus 1300 may include a processing unit 1301 and a transceiver unit 1302. Optionally, the processing unit 1301 may be coupled to the transceiver unit 1302. The processing unit 1301 may be configured to perform processing actions in the foregoing method embodiments. For example, the processing unit 1301 may be configured to perform at least one of the following actions: obtaining to-be-transmitted data, obtaining a plurality of data blocks based on the to-be-transmitted data, and generating information, data, a message, or a signal sent by the transceiver unit 1302, or performing processing on information, data, a message, or a signal received by the transceiver unit 1302.

For example, when the apparatus is configured to perform the method performed by the transmit end described in the foregoing embodiments, the processing unit 1301 may be configured to obtain to-be-sent data, and obtain a plurality of data blocks based on the to-be-sent data. The transceiver unit 1302 may be configured to compress a first data block based on a compression mode and send a compressed first data block.

Optionally, the transceiver unit 1302 may be configured to send at least one of compression mode information, a transmission time point of a previous data block, indication information of first duration, first information, second information, and third information. In addition, optionally, the transceiver unit 1302 may be further configured to receive at least one of feedback information, feedback information of the first duration, and the second information. For the compression mode information, the transmission time point of the previous data block, the indication information of the first duration, the first information, the second information, and the third information, refer to the descriptions in the foregoing method embodiment.

For example, when the apparatus is configured to perform the method performed by the receive end described in the foregoing embodiments, the transceiver unit 1302 may be configured to receive the compressed first data block, and the processing unit 1301 may be configured to decompress the first data block based on a compression mode of the first data block, and restore a plurality of data blocks including the first data block into the to-be-sent data.

Optionally, the transceiver unit 1302 may be configured to receive at least one of compression mode information, a transmission time point of a previous data block, indication information of first duration, first information, second information, and third information. In addition, optionally, the transceiver unit 1302 may be further configured to send at least one of feedback information, feedback information of the first duration, and second information. For the compression mode information, the transmission time point of the previous data block, the indication information of the first duration, the first information, the second information, and the third information, refer to the descriptions in the foregoing method embodiment.

Division into the modules in embodiments of this application is an example, is merely division into logical functions, and may be other division during actual implementation. In addition, functional modules in embodiments of this application may be integrated into one processor, or each of the modules may exist alone physically, or two or more modules may be integrated into one module. The integrated module may be implemented in the form of hardware, or may be implemented in a form of a software functional module.

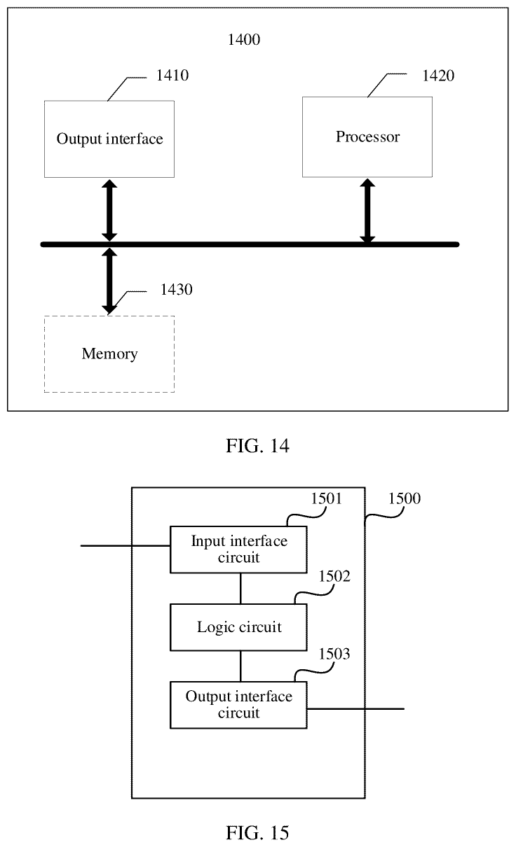

FIG. 14 shows a communication apparatus 1400 according to an embodiment of this application. The communication apparatus 1400 is configured to implement the data transmission method provided in this application. The communication apparatus 1400 may be a data transmission apparatus, a component in the data transmission apparatus, or an apparatus that can be used in a matching manner with the data transmission apparatus. The data transmission apparatus may be a terminal device or a network device. The communication apparatus 1400 may be a chip system or a chip. In this embodiment of this application, the chip system may include a chip, or may include a chip and another discrete component. The communication apparatus 1400 includes at least one processor 1420, configured to implement the data transmission method provided in embodiments of this application. The communication apparatus 1400 may further include an output interface 1410, and the output interface may also be referred to as an input/output interface. In this embodiment of this application, the output interface 1410 may be configured to communicate with another apparatus by using a transmission medium, and a function of the output interface 1410 may include sending and/or receiving. For example, when the communication apparatus 1400 is a chip, the communication apparatus 1400 performs transmission with another chip or component by using the output interface 1410. The processor 1420 may be configured to implement the method described in the foregoing method embodiments.

For example, when the apparatus is configured to perform the method performed by the transmit end described in the foregoing embodiments, the apparatus may include the output interface 1410 and the processor 1420. The output interface 1410 may be configured to obtain to-be-sent data, and the processor 1420 may be configured to obtain a plurality of data blocks based on the to-be-sent data. The transceiver unit may be configured to compress a first data block based on a compression mode and send a compressed first data block.

In addition, optionally, the output interface 1410 may be configured to send at least one of compression mode information, a transmission time point of a previous data block, indication information of first duration, first information, second information, and third information, or receive at least one of feedback information, feedback information of the first duration, and the second information. For example, when the apparatus is configured to perform the method performed by the receive end described in the foregoing embodiments, the apparatus may include the output interface 1410 and the processor 1420. The output interface 1410 may be configured to receive a compressed first data block, and the processor 1420 may be configured to obtain the first data block through decompression, and restore the to-be-transmitted data based on the plurality of data blocks including the first data block.

Optionally, the output interface 1410 may be further configured to receive at least one of compression mode information, a transmission time point of a previous data block, indication information of first duration, first information, second information, and third information, or send at least one of feedback information, feedback information of the first duration, and the second information.

Optionally, the communication apparatus 1400 may further include at least one memory 1430, configured to store program instructions and/or data. The memory 1430 is coupled to the processor 1420. The coupling in this embodiment of this application may be an indirect coupling or a communication connection between apparatuses, units, or modules in an electrical form, a mechanical form, or another form, and is used for information exchange between the apparatuses, the units, or the modules. The processor 1420 may operate with the memory 1430 together. The processor 1420 may execute the program instructions stored in the memory 1430. At least one of the at least one memory may be integrated with the processor.

In this embodiment of this application, the memory 1430 may be a non-volatile memory such as a hard disk drive (hard disk drive, HDD) or a solid-state drive (solid-state drive, SSD), or may be a volatile memory (volatile memory) such as a random-access memory (random-access memory, RAM). The memory is any other medium that can be used to include or store expected program code in a form of instructions or a data structure and that can be accessed by a computer, but is not limited thereto. The memory in embodiments of this application may alternatively be a circuit or any other apparatus that can implement a storage function, and is configured to store the program instructions and/or the data.

In this embodiment of this application, the processor 1420 may be a general purpose processor, a digital signal processor, an application-specific integrated circuit, a field programmable gate array or another programmable logic device, a discrete gate or a transistor logic device, or a discrete hardware component, and may implement or perform the method, steps, and logical block diagrams disclosed in embodiments of this application. The general purpose processor may be a microprocessor or any conventional processor or the like. The steps of the method disclosed with reference to embodiments of this application may be directly performed by a hardware processor, or may be performed by using a combination of hardware in the processor and a software module.

FIG. 15 shows a communication apparatus 1500 according to an embodiment of this application. The communication apparatus 1500 is configured to implement the data transmission method provided in this application. The communication apparatus 1500 may be a data transmission apparatus, a component in the data transmission apparatus, or an apparatus that can be used in a matching manner with the data transmission apparatus. The data transmission apparatus may be a terminal device or a network device. The data transmission apparatus 1500 may be a chip system or a chip. In this embodiment of this application, the chip system may include a chip, or may include a chip and another discrete component. A part or all of the data transmission method provided in the foregoing embodiments may be implemented by hardware or software. When the data transmission method is implemented by hardware, the data transmission apparatus 1500 may include an input interface circuit 1501, a logic circuit 1502, and an output interface circuit 1503. The input interface circuit 1501 and the output interface circuit 1503 may be respectively configured to implement receiving and sending actions. Optionally, for example, the apparatus is configured to implement a function of the transmit end. The input interface circuit 1501 may be configured to obtain to-be-transmitted data, the logic circuit 1502 may be configured to obtain a plurality of data blocks based on the to-be-transmitted data, and compress a first data block based on a compression mode. The output interface circuit 1503 may be configured to send compressed first data block. For another example, in an example in which the apparatus is configured to implement a function of the receive end, the input interface circuit 1501 may be configured to receive a compressed first data block, and the logic circuit 1502 may be configured to obtain the first data block through decompression, and restore the to-be-transmitted data based on the plurality of data blocks including the first data block.

Optionally, during specific implementation, the data transmission apparatus 1500 may be a chip or an integrated circuit.

Some or all of operations and functions performed by the data transmission apparatus described in the foregoing method embodiments of this application may be implemented by using the chip or the integrated circuit.

An embodiment of this application provides a computer-readable storage medium storing a computer program. The computer program includes instructions for performing the foregoing method embodiments.

An embodiment of this application provides a computer program product including instructions. The instructions, when executed on a computer, cause the computer to perform the foregoing method embodiments.

An embodiment of this application provides a communication system. Specifically, the communication system may include a receive end and a transmit end that are configured to implement the method shown in FIG. 3. For details, refer to the related descriptions in the foregoing method embodiments. Details are not described herein again. The communication system may include the structure shown in FIG. 1.

A person skilled in the art should understand that embodiments of this application may be provided as a method, a system, or a computer program product. Therefore, this application may use a form of hardware-only embodiments, software-only embodiments, or embodiments combining software and hardware. Moreover, this application may use a form of a computer program product that is implemented on one or more computer-usable storage media (including but not limited to a magnetic disk storage, a CD-ROM, an optical memory, and the like) that include computer-usable program code.

This application is described with reference to flowcharts and/or block diagrams of the method, the device (system), and the computer program product according to embodiments of this application. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine, so that the instructions executed by a computer or a processor of any other programmable data processing device generate an apparatus for implementing a specific function in one or more processes in the flowcharts and/or in one or more blocks in the block diagrams.

These computer program instructions may alternatively be stored in a computer-readable memory that can instruct a computer or another programmable data processing device to work in a specific manner, so that the instructions stored in the computer-readable memory generate an artifact that includes an instruction apparatus. The instruction apparatus implements a specific function in one or more processes in the flowcharts and/or in one or more blocks in the block diagrams.

These computer program instructions may alternatively be loaded onto a computer or another programmable data processing device, so that a series of operations and steps are performed on the computer or the another programmable device, thereby generating computer-implemented processing. Therefore, the instructions executed on the computer or the another programmable device provide steps for implementing a specific function in one or more processes in the flowcharts and/or in one or more blocks in the block diagrams.

Although preferred embodiments of this application are described, a person skilled in the art can make changes and modifications to these embodiments after they learn of a basic inventive concept. Therefore, the following claims are intended to be construed as to cover the preferred embodiments and all changes and modifications falling within the scope of this application.

It is clear that, a person skilled in the art may make various modifications and variations to embodiments of this application without departing from the scope of embodiments of this application. In this case, this application is intended to cover these modifications and variations of embodiments of this application provided that they fall within the scope of the claims of this application and their equivalent technologies thereof.

1. A data transmission method, comprising:
obtaining to-be-sent data;
obtaining a plurality of data blocks based on the to-be-sent data; and
compressing a first data block based on a compression mode and sending a compressed first data block, wherein the first data block is one of the plurality of data blocks.

2. The method according to claim 1, wherein the method further comprises:
sending compression mode information, wherein the compression mode information indicates the compression mode.

3. The method according to claim 2, wherein the compression mode information comprises one bit in a bitmap, and the bitmap indicates compression modes of the plurality of data blocks.

4. The method according to claim 2, wherein the compression mode information indicates that the compression mode is one of the following compression modes:
independent compression; and
reference compression, wherein the reference compression is to compress the first data block based on a previous data block.

5. The method according to claim 4, wherein the previous data block is a data block whose transmission time point is closest to a transmission time point of the first data block, and the previous data block is a successfully received data block; or
the previous data block is a data block that enables a compression rate of the first data block to be highest, and the previous data block is a successfully received data block.

6. The method according to claim 4, wherein the method further comprises:
sending the transmission time point of the previous data block.

7. The method according to claim 1, wherein the method further comprises:
receiving feedback information, wherein the feedback information indicates whether the first data block is received successfully.

8. The method according to claim 7, wherein an interval between a transmission time point of the feedback information and the transmission time point of the first data block is not less than k time units, and k is a positive integer.

9. The method according to claim 7, wherein the feedback information comprises information indicating that the first data block is received successfully; or
the feedback information comprises information indicating that a transmission unit is received successfully, and the transmission unit is occupied by the first data block.

10. The method according to claim 4, wherein a distance between the transmission time point of the previous data block and the transmission time point of the first data block does not exceed first duration, wherein
the first duration is a specified value, or the method further comprises:
receiving or sending indication information of the first duration.

11. The method according to claim 1, wherein the method further comprises:
sending first information, wherein the first information is used for determining a transmission unit occupied by the first data block or a quantity of transmission units occupied by the first data block.

12. The method according to claim 11, wherein the first information comprises at least one of the following information:
a number of a data block corresponding to a transmission unit in which the first information is located;
a quantity of data blocks corresponding to the transmission unit in which the first information is located;
location information of a transmission unit corresponding to a data block;
information indicating whether a data block is carried in different transmission units; and
information indicating that a data block ends.

13. The method according to claim 1, wherein the method further comprises:
receiving or sending second information, wherein the second information indicates a mapping relationship between the to-be-sent data and the plurality of data blocks.

14. The method according to claim 13, wherein
the second information specifically indicates that the to-be-sent data is evenly divided into the plurality of data blocks; or
the second information comprises a mapping relationship between a plurality of data segments of the to-be-sent data and a data block, wherein the mapping relationship is determined based on a proportion of data that is in the data segments and whose value is a specific value and a proportion of data that corresponds to the data block and whose value is the specific value; or
the to-be-sent data comprises three-dimensional data, and the second information comprises a mapping relationship between a data block and a coordinate range of the three-dimensional data; or
the to-be-sent data comprises data of an AI model, and the second information comprises a mapping relationship between a data block and a network layer of the AI model.

15. The method according to claim 7, wherein the feedback information indicates that the first data block is not received successfully, and the method further comprises:
sending third information, wherein the third information indicates to stop retransmitting the first data block.

16. A data transmission method, comprising:
receiving a compressed first data block;
decompressing the first data block based on a compression mode of the first data block; and
restoring a plurality of data blocks into to-be-sent data, wherein the plurality of data blocks comprise the first data block.

17. The method according to claim 16, wherein the method further comprises:
receiving compression mode information, wherein the compression mode information indicates the compression mode.

18. The method according to claim 17, wherein the compression mode information comprises one bit in a bitmap, and the bitmap indicates compression modes of the plurality of data blocks.

19. The method according to claim 17, wherein the compression mode information indicates that the compression mode is one of the following compression modes:
independent compression; and
reference compression, wherein the reference compression is to compress the first data block based on a previous data block.

20. The method according to claim 19, wherein the previous data block is a data block whose transmission time point is closest to a transmission time point of the first data block, and the previous data block is a successfully received data block; or
the previous data block is a data block that enables a compression rate of the first data block to be highest, and the previous data block is a successfully received data block.
